(19) United States
(12) Patent Application Publication
(10) Pub. No.: US 2026/0332100 A1
(43) Pub. Date: Oct. 22, 2026

(54) POWER AMPLIFIER CIRCUIT AND TRANSMISSION CIRCUIT EQUIPPED WITH THE SAME

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(21) Appl. No.: 19/468,423

(22) Filed: Feb. 3, 2026

Related U.S. Application Data
(63) Continuation of application No. PCT/JP2024/026451, filed on Jul. 24, 2024.

(30) Foreign Application Priority Data
Aug. 31, 2023 (JP) 2023-140777

(51) Int. Cl. H03F 1/02; H03F 3/60

(52) U.S. Cl. CPC H03F 1/0288; H03F 3/602; H03F 2200/09

(57) ABSTRACT

A power amplifier circuit includes an input terminal and an output terminal; a splitter; amplifiers; a phase adjuster; a substrate; and a substrate that is mounted on the substrate. The splitter is connected to the input terminal and distributes an input signal from the input terminal into a first path and a second path. The amplifier is connected to the first path for the splitter. The amplifier is connected to the second path for the splitter. The phase adjuster is connected between an output of the amplifier and an output of the amplifier. The amplifiers configure a Doherty amplifier. The output terminal is electrically connected to a connection node between the second amplifier and the phase adjuster. The amplifier is a carrier amplifier and is formed at the substrate. The amplifier is a peak amplifier and is formed at the substrate.

### CROSS REFERENCE TO RELATED APPLICATION

This is a continuation of International Application No. PCT/JP2024/026451 filed on Jul. 24, 2024 which claims priority from Japanese Patent Application No. 2023-140777 filed on Aug. 31, 2023. The contents of these applications are incorporated herein by reference in their entireties.

### BACKGROUND OF THE DISCLOSURE

### Field of the Disclosure

The present disclosure relates to a power amplifier circuit and a transmission circuit equipped with the same, and more particularly, to a configuration of a power amplifier circuit suitable for high frequency signals in sub-terahertz frequency bands.

### Description of the Related Art

In U.S. Patent Application Publication No. 2022/0416725, a Doherty amplifier that can be used in a wireless communication system is disclosed. In U.S. Patent Application Publication No. 2022/0416725, a power amplifier in the final stage at each amplifier path including a carrier amplifier and a peak amplifier of a Doherty amplifier is implemented by using an IC die made of a group III-V material such as gallium nitride (GaN). In contrast, a driver-stage amplifier for driving the power amplifier in the final stage is implemented by using an IC die made of a Si-based material such as silicon-germanium (SiGe) or an IC die made of a group III-V material.

### BRIEF SUMMARY OF THE DISCLOSURE

In recent years, for wireless communication apparatuses, development of communication in frequency bands exceeding 100 GHz, which are so-called sub-terahertz frequency bands, has progressed. Since a spectrum band width can be increased by using sub-terahertz frequency bands, high-capacity, high-speed communications with, for example, 100 Gbps or more, can be achieved.

In contrast, in the case of signals in frequency bands exceeding 100 GHz, loss in a semiconductor configuring an amplifier tends to be large, compared to cases where signals in millimeter wave bands or lower frequency bands are used. Therefore, it is important to use a low-loss semiconductor in an amplifier circuit supporting sub-terahertz frequency bands.

As a material for a low-loss semiconductor mentioned above, a material containing, as a main component, a compound of an element from group III and an element from group V (hereinafter, may also be referred to as a “group III-V compound”) disclosed in U.S. Patent Application Publication No. 2022/0416725 is known. Since the power density of such a material is higher than those of Si-based materials, which have been used in the related art, loss can be significantly reduced compared to semiconductors formed of Si-based materials. However, the group III-V compound is more expensive than Si-based materials. Therefore, if all the circuits in a Doherty amplifier are made from the group III-V compound, the cost of the entire apparatus increases.

The present disclosure has been designed to solve the problem mentioned above, and a possible benefit of the present disclosure is to suppress a cost increase and improve circuit efficiency by reducing loss in a power amplifier circuit supporting sub-terahertz frequency bands.

A power amplifier circuit according to the present disclosure includes an input terminal and an output terminal; a splitter; a first amplifier and a second amplifier; a first phase adjuster; a first substrate; and a second substrate mounted on the first substrate. The splitter is connected to the input terminal and distributes an input signal from the input terminal into a first path and a second path. The first amplifier is connected to the first path for the splitter. The second amplifier is connected to the second path for the splitter. The first phase adjuster is connected between an output of the first amplifier and an output of the second amplifier. The first amplifier is formed at the first substrate. The second amplifier is formed at the second substrate. The first amplifier and the second amplifier configure a Doherty amplifier. The first amplifier is a carrier amplifier and the second amplifier is a peak amplifier. The output terminal is electrically connected to a connection node between the second amplifier and the first phase adjuster. The first substrate is a semiconductor substrate including a material containing a Si-based base material as a main component. The second substrate is a semiconductor substrate including a material containing, as a main component, a compound of an element from group III and an element from group V.

In a power amplifier circuit according to the present disclosure, a carrier amplifier (first amplifier) configuring a Doherty amplifier is formed at a semiconductor substrate made of a Si-based base material, and a peak amplifier (second amplifier) configuring the Doherty amplifier is formed at a semiconductor substrate made of a base material of a group III-V compound. Typical Doherty amplifiers adopt a configuration in which a Class A amplifier or a Class AB amplifier with a relatively low distortion is caused to operate at a saturated output as a carrier amplifier and a Class C amplifier with a high efficiency is driven as a peak amplifier simultaneously with the carrier amplifier at the time of a high output. Thus, a cost increase can be suppressed by using, for a carrier amplifier, a semiconductor substrate made of a Si-based material, and loss can be reduced to improve circuit efficiency by using, for a peak amplifier that requires a high efficiency, a semiconductor substrate made of a group III-V compound.

### BRIEF DESCRIPTION OF THE SEVERAL VIEWS OF THE DRAWINGS

FIG. 1 is a circuit diagram of a transmission circuit to which a power amplifier circuit according to a first embodiment is applied.

FIG. 2 is a perspective side view of the transmission circuit in FIG. 1.

Each of FIGS. 3A, 3B and 3C is a diagram for explaining tracking modes for adjusting a power supply voltage level.

FIG. 4 is a diagram for explaining operation of a Doherty amplifier.

FIG. 5 is a perspective side view of a transmission circuit according to a second embodiment.

FIG. 6 is a partial circuit diagram of a transmission circuit according to a third embodiment.

FIG. 7 is a partial circuit diagram of a transmission circuit according to a fourth embodiment.

FIG. 8 is a partial circuit diagram of a transmission circuit according to a fifth embodiment.

FIG. 9 is a partial circuit diagram of a transmission circuit according to a sixth embodiment.

FIG. 10 is a perspective side view of a transmission circuit according to a seventh embodiment.

FIG. 11 is a perspective side view of a transmission circuit according to an eighth embodiment.

FIG. 12 is a perspective side view of a transmission circuit according to a ninth embodiment.

FIG. 13 is a perspective side view of a transmission circuit according to a modification.

### DETAILED DESCRIPTION OF THE DISCLOSURE

Hereinafter, embodiments of the present disclosure will be described in detail with reference to the drawings. In the drawings, the same signs are assigned to the same or corresponding parts, and repetitive description of those same or corresponding parts will be omitted.

### First Embodiment

### Configurations of Transmission Circuit and Power Amplifier Circuit

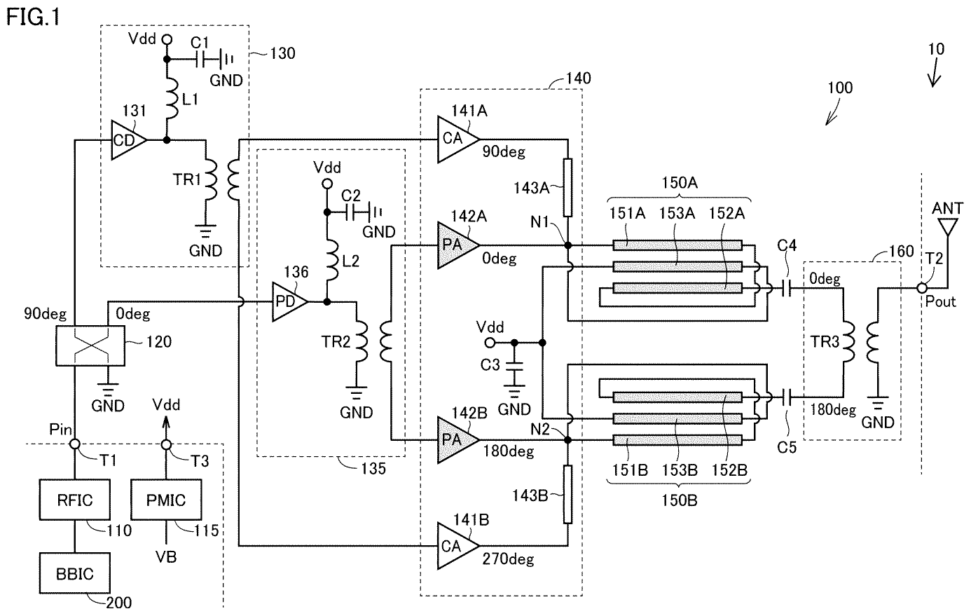

FIG. 1 is a circuit diagram of a transmission circuit 10 to which a power amplifier circuit 100 according to a first embodiment is applied. A portable terminal such as a mobile phone, a smartphone, or a tablet or a communication apparatus having a communication function, such as a personal computer, is equipped with the transmission circuit 10.

Referring to FIG. 1, the transmission circuit 10 includes an antenna ANT, a radio frequency integrated circuit (RFIC) 110 as a power supply circuit, a power management integrated circuit (PMIC), and a baseband integrated circuit (BBIC) 200 configuring a baseband signal processing circuit, in addition to the power amplifier circuit 100.

In the transmission circuit 10, the RFIC 110 up-converts an intermediate frequency (IF) signal transmitted from the BBIC 200 into a high frequency (radio frequency (RF)) signal, the power amplifier circuit 100 amplifies the high frequency signal, and the amplified signal is radiated from the antenna ANT.

The power amplifier circuit 100 includes an input terminal T1, an output terminal T2, a power supply terminal T3, a splitter 120, preamplifiers 130 and 135, a power amplifier stage 140, transmission line transformers (TLTs) 150A and 150B, and a conversion circuit 160. The power amplifier stage 140 is a so-called “Doherty amplifier” including carrier amplifiers 141A and 141B and peak amplifiers 142A and 142B.

The power amplifier circuit 100 receives, at the input terminal T1, an input signal Pin from the RFIC 110, amplifies the input signal Pin, and outputs, through the output terminal T2, the amplified signal to the antenna ANT.

The PMIC 115 is a power supply circuit for supplying driving power for operating the power amplifier circuit 100. The PMIC 115 includes, for example, a plurality of DC/DC converters and converts a battery voltage VB supplied from an external battery into a plurality of different voltage levels. The PMIC 115 supplies a power supply voltage Vdd to the power supply terminal T3 of the power amplifier circuit 100. As described later, the power supply voltage Vdd is used as a driving power supply for amplifiers in the power amplifier circuit 100.

The input signal Pin received at the input terminal T1 is transmitted to the splitter 120. The splitter 120 is a so-called hybrid coupler and includes two input terminals and two output terminals. The input signal Pin is inputted to one of the input terminals. The other input terminal is connected to a ground potential GND. With the hybrid coupler connected as described above, the input signal Pin is outputted through two paths: an output terminal connected to a first path and an output terminal connected to a second path.

At this time, the signal outputted into the first path and the signal outputted into the second path have a phase difference of 90 degrees. More specifically, the phase of the signal in the first path is advanced with respect to the phase of the signal in the second path by 90 degrees. That is, the hybrid coupler has not only a function as a splitter but also a function as a phase adjuster. The signal splitting function and the phase adjusting function may be implemented by separate circuits.

The first path for the splitter 120 is connected to the preamplifier 130, and the second path for the splitter 120 is connected to the preamplifier 135. The preamplifier 130 is a driving circuit for driving the carrier amplifiers 141A and 141B in the power amplifier stage 140. Similarly, the preamplifier 135 is a driving circuit for driving the peak amplifiers 142A and 142B in the power amplifier stage 140.

The preamplifier 130 includes a driving amplifier 131 for carrier amplifiers and a conversion transformer TR1. A power supply voltage Vdd is supplied through an inductor L1 to an output terminal of the driving amplifier 131. Furthermore, a capacitor C1 is connected between a supply terminal for the power supply voltage Vdd and a ground potential GND. The inductor L1 is, for example, a λ/4 line. Since the supply terminal for the power supply voltage Vdd is short-circuited by the capacitor C1, when the supply terminal is seen from an output end of the driving amplifier 131, a power line appears open, due to the inductor L1 as the λ/4 line. The capacitor C1 is a so-called bypass capacitor and suppresses voltage variations of the power supply voltage Vdd. The driving amplifier 131 amplifies a signal transmitted from the splitter 120 and transmits the amplified signal to the conversion transformer TR1.

The conversion transformer TR1 is a circuit for converting an unbalanced line into a balanced line. The driving amplifier 131 is connected to a first end of a primary winding of the conversion transformer TR1, and a second end of the primary winding is connected to a ground potential GND. A first end of a secondary winding of the conversion transformer TR1 is connected to the carrier amplifier 141A, and a second end of the secondary winding is connected to the carrier amplifier 141B.

Due to the conversion transformer TR1, the phase of a signal transmitted to the carrier amplifier 141A is opposite to the phase of a signal transmitted to the carrier amplifier 141B. As described above, due to the hybrid coupler as the splitter 120, the phase of a signal supplied to the preamplifier 130 is advanced with respect to the phase of a signal supplied to the preamplifier 135 by 90 degrees. Thus, with respect to the phase of a signal supplied to the preamplifier 135, the phase of a signal transmitted to the carrier amplifier 141A is advanced by 90 degrees. Furthermore, the phase of a signal transmitted to the carrier amplifier 141B is delayed by 90 degrees, in other words, is advanced by 270 degrees.

The preamplifier 135 includes a driving amplifier 136 for peak amplifiers and a conversion transformer TR2. A power supply voltage Vdd is supplied through an inductor L2 to an output terminal of the driving amplifier 136. Furthermore, a capacitor C2 is connected between a supply terminal for the power supply voltage Vdd and a ground potential GND. As described above for the preamplifier 130, when the supply terminal is seen from an output end of the driving amplifier 136, a power line appears open, due to the inductor L2 as a λ/4 line. Furthermore, voltage variations of the power supply voltage Vdd are suppressed by the capacitor C2 as a bypass capacitor. The driving amplifier 136 amplifies a signal transmitted from the splitter 120 and transmits the amplified signal to the conversion transformer TR2.

The conversion transformer TR2 is a circuit for converting an unbalanced line into a balanced line. The driving amplifier 136 is connected to a first end of a primary winding of the conversion transformer TR2, and a second end of the primary winding is connected to a ground potential GND. A first end of a secondary winding of the conversion transformer TR2 is connected to the peak amplifier 142A, and a second end of the secondary winding is connected to the peak amplifier 142B.

Due to the conversion transformer TR2, the phase of a signal transmitted to the peak amplifier 142A is opposite to the phase of a signal transmitted to the peak amplifier 142B. Thus, with respect to the phase of a signal supplied to the preamplifier 135, the phase of a signal transmitted to the peak amplifier 142A is the same as the phase of a signal supplied to the preamplifier 135. Furthermore, the phase of a signal transmitted to the peak amplifier 142B is delayed (or advanced) with respect to the phase of the signal supplied to the preamplifier 135 by 180 degrees.

The power amplifier stage 140 includes phase adjusters 143A and 143B, in addition to the carrier amplifiers 141A and 141B and the peak amplifiers 142A and 142B. The phase adjuster 143A is connected between an output terminal of the carrier amplifier 141A and an output terminal of the peak amplifier 142A. A connection node N1 between the phase adjuster 143A and the peak amplifier 142A is connected to the TLT 150A. Furthermore, the phase adjuster 143B is connected between an output terminal of the carrier amplifier 141B and an output terminal of the peak amplifier 142B. A connection node N2 between the phase adjuster 143B and the peak amplifier 142B is connected to the TLT 150B.

The phase adjusters 143A and 143B adjust phases of signals amplified by the carrier amplifiers 141A and 141B, respectively. The phase adjusters 143A and 143B are, for example, ¼ wavelength transmission lines and are capable of delaying the phases of the signals amplified by the carrier amplifiers 141A and 141B, respectively, by 90 degrees. Thus, at the connection node N1, the phase of an output from the carrier amplifier 141A and the phase of an output signal from the peak amplifier 142A are the same. Similarly, at the connection node N2, the phase of an output from the carrier amplifier 141B and the phase of an output from the peak amplifier 142B are the same.

Furthermore, the phase adjusters 143A and 143B are capable of rotating load impedance by 180 degrees on a Smith chart. That is, the phase adjusters 143A and 143B also function as impedance inverters.

Herein, a “connection node” does not represent a specific point on a path, and a different position in a circuit is also regarded as the “connection node” as long as the position is electrically the same (same potential) position. For example, in FIG. 1, even a position that is different from a point indicated as “N1” in a circuit corresponds to the “connection node N1” as long as the position is on a line connecting an output end of the peak amplifier 142A to the phase adjuster 143A.

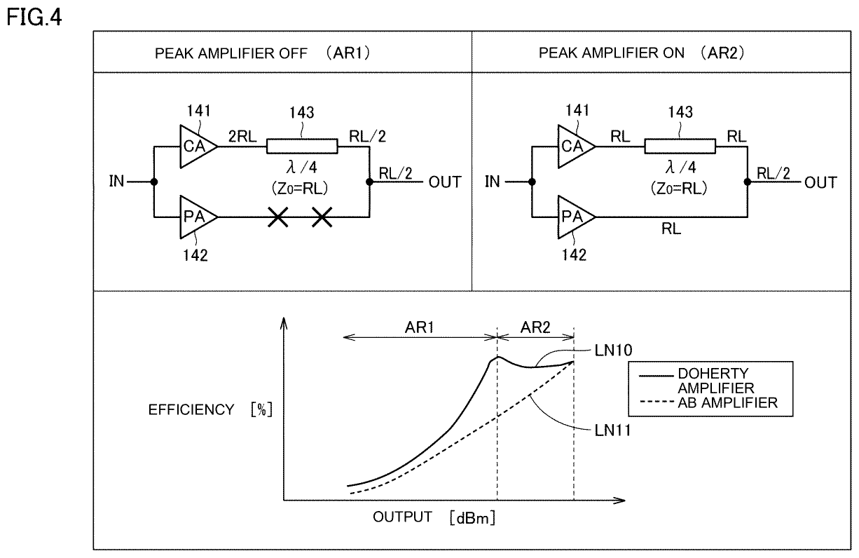

The power amplifier stage 140 functions as a Doherty amplifier. As described later with reference to FIG. 4, in the Doherty amplifier, the carrier amplifiers 141A and 141B are always operating, whereas the peak amplifiers 142A and 142B operate only at the time of a high output. As the carrier amplifiers 141A and 141B, Class A amplifiers or Class AB amplifiers with a relatively low distortion are used. In contrast, as the peak amplifiers 142A and 142B, Class C amplifiers are used. With the use of Class C amplifiers as the peak amplifiers 142A and 142B, when the voltage level of an input signal reaches a predetermined value or lower, the peak amplifiers 142A and 142B stop amplifying operations.

Each of the TLTs 150A and 150B is an impedance converter including three parallel lines each having a line length of ⅛ wavelength to ¼ wavelength.

The TLT 150A includes a first line 151A, a second line 152A, and a third line 153A. A first end of the first line 151A is connected to the connection node N1 of the power amplifier stage 140. A second end of the first line 151A is connected to a first end of the second line 152A. A second end of the second line 152A is connected to the conversion circuit 160 with a capacitor C4 interposed therebetween. A direct current component in a signal that has passed through the TLT 150A is eliminated by the capacitor C4.

A power supply voltage Vdd is supplied to a first end of the third line 153A, and a second end of the third line is connected to the connection node N1. The power supply voltage Vdd is supplied, as a driving power supply for the carrier amplifier 141A and the peak amplifier 142A, through the third line 153A. A capacitor C3 is a bypass capacitor that is connected between a supply terminal for the power supply voltage Vdd and a ground potential GND. Voltage variations of the power supply voltage Vdd are suppressed by the capacitor C3.

The first line 151A, the second line 152A, and the third line 153A are arranged in parallel so that currents flow in the same direction. Furthermore, the third line 153A is arranged to be coupled to the first line 151A and the second line 152A. By arranging the three lines as described above, the TLT 150A functions as an impedance converter.

Similarly, the TLT 150B includes a first line 151B, a second line 152B, and a third line 153B. A first end of the first line 151B is connected to the connection node N2 of the power amplifier stage 140. A second end of the first line 151B is connected to a first end of the second line 152B. A second end of the second line 152B is connected to the conversion circuit 160 with a capacitor C5 interposed therebetween. A direct current component in a signal that has passed through the TLT 150B is eliminated by the capacitor C5.

The power supply voltage Vdd is supplied to a first end of the third line 153B, and a second end of the third line 153B is connected to the connection node N2. The power supply voltage Vdd is supplied, as a driving power supply for the carrier amplifier 141B and the peak amplifier 142B, through the third line 153B. Voltage variations of the power supply voltage Vdd are suppressed by the capacitor C4 as a bypass capacitor, which is connected between the supply terminal for the power supply voltage Vdd and the ground potential GND.

The first line 151B, the second line 152B, and the third line 153B are arranged in parallel so that currents flow in the same direction. Furthermore, the third line 153B is arranged to be coupled to the first line 151B and the second line 152B. By arranging the three lines as described above, the TLT 150B functions as an impedance converter.

The conversion circuit 160 is a circuit for converting a balanced line into an unbalanced line. The conversion circuit 160 includes a magnetic coupled transformer (MCT) TR3. A first end of a primary winding of the magnetic coupled transformer TR3 is connected to the second line 152A of the TLT 150A with the capacitor C4 interposed therebetween. Furthermore, a second end of the primary winding of the magnetic coupled transformer TR3 is connected to the second line 152B of the TLT 150B with the capacitor C5 interposed therebetween. A first end of a secondary winding of the magnetic coupled transformer TR3 is connected to the antenna ANT with the output terminal T2 interposed therebetween, and a second end of the secondary winding is connected to a ground potential GND.

The phase of an output signal from the TLT 150A is opposite to the phase of an output signal from the TLT 150B. Therefore, due to the magnetic coupled transformer TR3, the phase of the output signal from the TLT 150A and the phase of the output signal from the TLT 150B are the same. Accordingly, the two signals from the TLT 150A and the TLT 150B are combined together into an output signal Pout.

As described above, with the configuration in which the input signal Pin is distributed into two paths and the distributed signals are amplified at the paths by a Doherty amplifier and combined together, the power amplifier circuit 100 can achieve high-efficiency signal amplification.

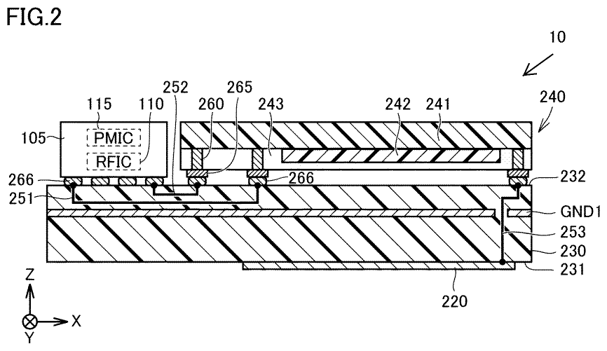

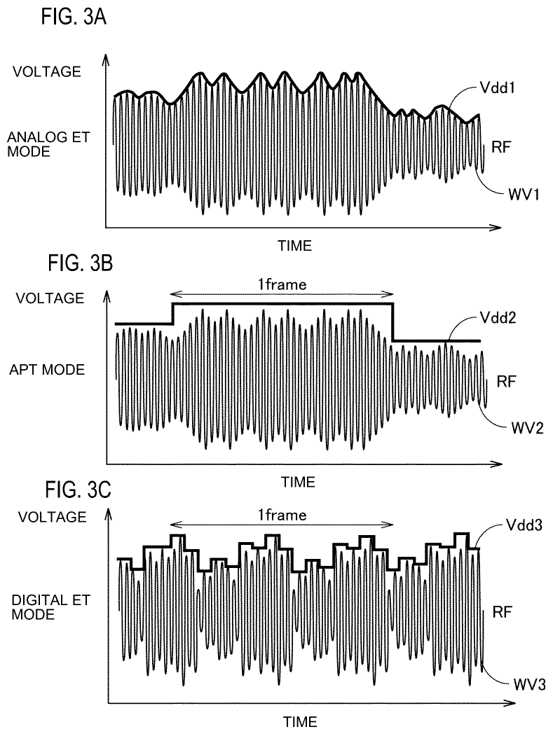

FIG. 2 is a perspective side view of the transmission circuit 10 described above with reference to FIG. 1. Referring to FIG. 2, the transmission circuit 10 includes a radiating element 220, a dielectric substrate 230, a system in package (SiP) module 105, and an amplifier module 240 in which the power amplifier circuit 100 is formed. In perspective side views in FIG. 2 and later figures, a normal direction of a main face of the dielectric substrate 230 is defined as a Z-axis, and a face perpendicular to the Z-axis is defined as an XY-plane. In FIG. 2, a horizontal direction is represented by an X-axis direction, and a depth direction is defined as a Y-axis direction.

The dielectric substrate 230 includes a main face 231 (first face) and a main face 232 (second face) that are two faces opposite to each other. The dielectric substrate 230 is a low temperature co-fired ceramics (LTCC) multilayer substrate, a multilayer resin substrate formed by laminating multiple resin layers made of resin such as epoxy or polyimide, a multilayer resin substrate formed by laminating multiple resin layers made of liquid crystal polymer (LCP) having a lower permittivity, a multilayer resin substrate formed by laminating multiple resin layers made of fluorine-based resin, or a ceramic multilayer substrate made of a material other than LTCC. The dielectric substrate 230 does not necessarily have a multilayer structure and may be a single-layer substrate.

The radiating element 220 corresponds to the antenna ANT in FIG. 1. The radiating element 220 is arranged on the main face 231 (a face in the Z-axis negative direction) of the dielectric substrate 230. In the example of FIG. 2, the radiating element 220 is a patch antenna of a flat plate shape. In FIG. 2, an example in which the radiating element 220 is exposed on a surface of the main face 231 is illustrated. However, the radiating element 220 may be arranged at an inner layer of the dielectric substrate 230.

In the dielectric substrate 230, a ground electrode GND1 is arranged over the entire dielectric layer between the radiating element 220 and the main face 232 in such a manner that the ground electrode GND1 and the radiating element 220 are opposite to each other.

The amplifier module 240 includes a semiconductor substrate 241 and a semiconductor substrate 242. The semiconductor substrate 242 is arranged on a main face in the Z-axis negative direction of the semiconductor substrate 241 and is electrically connected to the semiconductor substrate 241. The semiconductor substrate 242 is molded with an insulative resin 243.

The amplifier module 240 is mounted on the main face 232 of the dielectric substrate 230. The semiconductor substrate 241 is electrically connected to the dielectric substrate 230 with columnar electrodes 260 arranged in the resin 243 for molding, connecting electrodes 265, and solder bumps 266 interposed therebetween.

The semiconductor substrate 241 is, for example, a semiconductor substrate made of a Si-based base material such as silicon-germanium (SiGe). In contrast, the semiconductor substrate 242 is a semiconductor substrate made of a base material containing, as a main component, a compound of an element from group III and an element from group V, such as gallium nitride (GaN), gallium arsenide (GaAs), or indium phosphide (InP).

The peak amplifiers 142A and 142B of the power amplifier stage 140 in the power amplifier circuit 100 in FIG. 1 are formed at the semiconductor substrate 242. In contrast, at the semiconductor substrate 241, circuits other than the peak amplifiers 142A and 142B in the power amplifier circuit 100 are formed.

The SiP module 105 is a circuit module including the RFIC 110 and the PMIC 115 in FIG. 1 and a power inductor (not illustrated in the drawing) for power. The SiP module 105 is mounted on the main face 232 of the dielectric substrate 230 with the solder bumps 266 interposed therebetween.

A high frequency signal and a power supply voltage from the SiP module 105 are transmitted, through power supply wires 251 and 252 arranged inside the dielectric substrate 230, to the amplifier module 240. Furthermore, the output signal Pout amplified by the power amplifier circuit 100 is transmitted, through a power supply wire 253, to the radiating element 220.

An example in which the radiating element 220 is a patch antenna has been described above. However, the radiating element 220 may be a linear antenna, such as a monopole antenna or a dipole antenna, and/or an antenna with other configurations such as a slot antenna. Depending on the type of the radiating element 220, part of or the entire ground electrode GND1 in the dielectric substrate 230 is eliminated.

Dealing with Sub-Terahertz Frequency Bands

In recent years, for wireless communication apparatuses, in order to implement high-capacity, high-speed communications, development of communication in frequency bands exceeding 100 GHz, which are so-called sub-terahertz frequency bands, has progressed. Signals in high frequency bands such as sub-terahertz frequency bands tend to be easily attenuated compared to signals in low frequency bands. Furthermore, sub-terahertz frequency bands may be used for a wide band width exceeding 3 GHz or more. Therefore, in power amplifier apparatuses used for signals in sub-terahertz frequency bands, a power amplifier circuit needs to be controlled in a method that is different from a method used for the case where signals in lower frequency bands are used.

### (1) About Tracking Modes

For adjustment of a power supply voltage level in a power amplifier, some tracking modes for signals transmitted have been known. The tracking modes are typically divided into major categories: an envelope tracking mode and an average power tracking (APT) mode. The envelope tracking mode is categorized into a “digital envelope tracking mode (digital ET mode)” and an “analog envelope tracking mode (analog ET mode)”. The envelope tracking mode is a mode in which the level of a power supply voltage is set based on an envelope signal indicating the envelope of an input signal. In contrast, the APT mode is a mode in which the level of a power supply voltage is set based on an average output power in a predetermined period, instead of an envelope signal.

Each of FIGS. 3A, 3B and 3C is a diagram for explaining the overview of the individual tracking modes. In FIGS. 3A, 3B and 3C, a graph indicating an example of transition of power supply voltage in the analog ET mode is illustrated in FIG. 3A. A graph indicating an example of transition of power supply voltage in the APT mode is illustrated in FIG. 3B, and a graph indicating an example of transition of power supply voltage in the digital ET mode is illustrated in FIG. 3C. In each of the graphs, time is indicated on the horizontal axis, and voltage is indicated on the vertical axis. Thick solid lines Vdd1 to Vdd3 indicate the power supply voltage in the individual modes, and thin solid lines WV1 to WV3 indicate the output signal Pout, which is a modulated high frequency signal.

In the analog ET mode (FIG. 3A), a power supply voltage that continuously varies following the envelope of the input signal Pin is set. The waveform of the power supply voltage in the analog ET mode is an analog waveform, not a digital waveform.

In the analog ET mode, a power supply voltage corresponding to variations in the amplitude of the input signal Pin is constantly supplied. Therefore, the analog ET mode may provide the most efficient tracking. However, since the power supply voltage needs to be continuously varied, the power supply voltage may fail to follow the envelope of a modulated high frequency signal in the case where the amplitude of an input signal varies largely or the modulation band width of the input signal is wide.

Next, in the case of the APT mode in FIG. 3B, the voltage level of the power supply voltage is different for every predetermined frame unit. The power supply voltage has a digital waveform and forms a rectangular wave. A frame represents a unit of a modulated high frequency signal. For example, the length of a frame is 10 milliseconds.

Specifically, in the APT mode, the voltage level of the power supply voltage is determined based on the average output power, not based on an envelope signal. In this case, there is no need to vary the power supply voltage quickly to follow the input signal Pin. However, since a voltage larger than the input signal Pin is set for each frame, improvement may be needed in terms of power saving and efficiency.

In the digital ET mode (FIG. 3C), the power supply voltage is set at a plurality of different voltage levels within a frame. The power supply voltage has a digital waveform and forms a rectangular wave. Specifically, in the digital ET mode, a voltage level corresponding to the voltage of the input signal Pin in a target section in a frame is selected, based on an envelope signal, from among the plurality of different voltage levels. At this time, the voltage level is selected so that the envelope of a carrier wave modulated based on transmission information can be tracked. More specifically, a voltage level corresponding to an envelope value of each symbol is selected with reference to the range of an envelope value associated with each of the plurality of different voltage levels.

In the case of signals in sub-terahertz frequency bands, a power supply voltage needs to follow changes in an input signal of high frequencies and a wide modulation band width. Therefore, the changes cannot be followed in the analog ET mode, and the digital ET mode needs to be used.

### (2) About Doherty Amplifier

Doherty amplifiers have been known as a configuration for improving the amplification efficiency of a power amplifier circuit. Schematically, a Doherty amplifier has a configuration in which a carrier amplifier and a peak amplifier are connected in parallel between an input terminal and an output terminal, and a phase adjuster functioning as an impedance inverter is arranged between the carrier amplifier and a composition node. The carrier amplifier operates when output power is small, and both the carrier amplifier and the peak amplifier operate when the output power is larger than a predetermined value.

FIG. 4 is a diagram for explaining operation of a Doherty amplifier. In FIG. 4, a circuit state and load impedance when the peak amplifier 142 is operating (right column) and when the peak amplifier 142 is not operating (left column) are illustrated in an upper part, and the relationship between output power and efficiency of the Doherty amplifier is illustrated, in comparison with the case of an AB amplifier, in a lower part. In the lower part, a solid line LN10 represents efficiency for the case of the Doherty amplifier, and a broken line LN11 represents efficiency for the case of the AB amplifier.

In the case where both the carrier amplifier 141 and the peak amplifier 142 are operating (right column in the upper part), the load impedance seen from each of the carrier amplifier 141 and the peak amplifier 142 is represented by RL, and the load impedance at the composition point (output terminal) is represented by RL/2. In contrast, in the case where the peak amplifier 142 is turned off (left column in the upper part), the load impedance seen from the carrier amplifier 141 is represented by 2RL, due to the phase adjuster 143 functioning as an impedance inverter.

In typical amplifiers, efficiency tends to increase as load impedance increases. Therefore, as indicated by the graph in the lower part, with the use of the Doherty amplifier, the efficiency of the carrier amplifier 141 can be increased due to an increase of the load impedance in an area AR1 where the peak amplifier 142 is turned off, compared to the case of the AB amplifier that is capable of outputting the same peak power. Furthermore, in an area AR2 where the peak amplifier 142 is turned on, efficiency can be increased because of a parallel operation of the carrier amplifier 141 and the peak amplifier 142.

Since signals in sub-terahertz frequency bands have characteristics of being easily attenuated compared to signals in low frequency bands, a highly efficient amplifier needs to be used. Therefore, use of the Doherty amplifier mentioned above is effective to improve efficiency.

(3) Materials for semiconductor substrates

A semiconductor device such as a transistor is used for an amplifier. As a semiconductor substrate for forming such a semiconductor device, a Si-based material that is relatively inexpensive and suitable for mass production is typically used. However, in the case of a Si-based material, since loss tends to be large in sub-terahertz frequency bands exceeding 100 GHz, characteristics required for semiconductor devices may be unachievable by the Si-based material.

In contrast, since a group III-V compound such as GaN, GaAs, or InP has a power density higher than a Si-based material, characteristics of low loss compared to a substrate made of a Si-based material can be achieved even in sub-terahertz frequency bands. Meanwhile, in the current situation, the unit cost of a material for a group III-V compound is higher than the unit cost of a Si-based material, and the production cost for the case of a group III-V compound is still high. Therefore, producing the entire amplifier circuit by using a semiconductor substrate made of a group III-V compound as a base material may cause an increase in the cost of the entire circuit.

Thus, in the first embodiment, a Doherty amplifier is used for a power amplifier circuit, a peak amplifier that operates at the time of a high output and needs to have low-loss and high-efficiency characteristics is formed at a semiconductor substrate made of a group III-V compound, and a carrier amplifier and other circuits are formed at a semiconductor substrate made of a Si-based base material, which is relatively inexpensive. Thus, in sub-terahertz frequency bands, an increase in the cost of the entire power amplifier circuit can be suppressed, and the circuit efficiency can be improved by suppressing an increase of loss at the time of a high output.

The “carrier amplifier 141A”, the “peak amplifier 142A”, the “carrier amplifier 141B”, and the “peak amplifier 142B” in the first embodiment correspond to a “first amplifier”, a “second amplifier”, a “third amplifier”, and a “fourth amplifier”, respectively, in the present disclosure. The “phase adjuster 143A” and the “phase adjuster 143B” in the first embodiment correspond to a “first phase adjuster” and a “second phase adjuster”, respectively, in the present disclosure. The “semiconductor substrate 241” and the “semiconductor substrate 242” in the first embodiment correspond to a “first substrate” and a “second substrate”, respectively, in the present disclosure. The “preamplifier 130” and the “preamplifier 135” in the first embodiment correspond to a “first preamplifier” and a “second preamplifier”, respectively, in the present disclosure. The “TLT 150A” and the “TLT 150B” in the first embodiment correspond to a “first transmission line transformer” and a “second transmission line transformer”, respectively, in the present disclosure. The “first line 151A, the “second line 152A”, the “third line 153A”, the “first line 151B”, the “second line 152B”, and the “third line 153B” in the first embodiment correspond to a “first line”, a “second line”, a “third line”, a “fourth line”, a “fifth line”, and a “sixth line”, respectively, in the present disclosure.

### Second Embodiment

In a second embodiment, a configuration in which an RFIC is formed at a semiconductor substrate will be described.

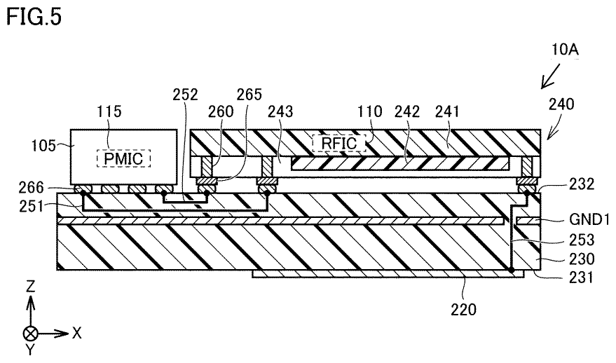

FIG. 5 is a perspective side view of a transmission circuit 10A according to the second embodiment. The transmission circuit 10A is different from the transmission circuit according to the first embodiment in FIG. 2 in that the RFIC 110 is formed at the semiconductor substrate 241 not at the SiP module 105. The other features are the same as those in FIG. 2. In FIG. 5, description of elements overlapping with those in FIG. 2 is not provided.

In the case of signals in sub-terahertz frequency bands, loss caused by a transmission line tends to be large compared to signals in lower frequency bands. Therefore, it is desirable that the length of a path from the RFIC 110 to the radiating element 220 be as short as possible.

In the case of the transmission circuit 10 according to the first embodiment, since the RFIC 110 is included in the SiP module 105, a transmission signal that has been up-converted by the RFIC 110 travels through the power supply wire 251 in the dielectric substrate 230, passes through the semiconductor substrates 241 and 242 and the power supply wire 253, and is transmitted to the radiating element 220.

In contrast, as in the transmission circuit 10A, by forming the RFIC 110 at the semiconductor substrate 241, an IF signal can be transmitted through a path from the SiP module 105 to the semiconductor substrate 241, and the length of the path through which a high frequency signal is transmitted can be shortened. Thus, since loss caused by a power supply wire is reduced, the circuit efficiency can further be improved.

### Third Embodiment

In a third embodiment, other configurations of a conversion circuit will be described.

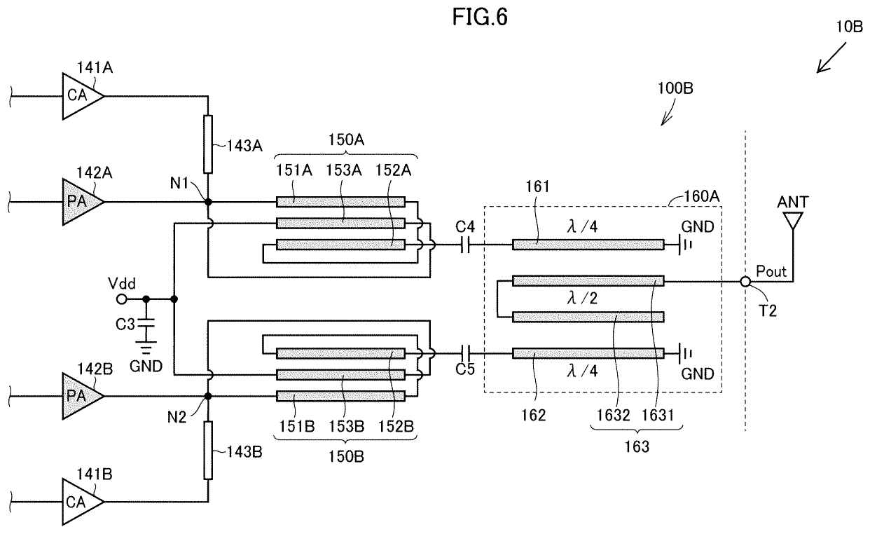

FIG. 6 is a partial circuit diagram of a transmission circuit 10B according to the third embodiment. In FIG. 6, the power amplifier stage 140 and circuits downstream the power amplifier stage 140 in a power amplifier circuit 100B are illustrated. The power amplifier circuit 100B has a configuration in which the conversion circuit 160 in the power amplifier circuit 100 in FIG. 1 is replaced by a conversion circuit 160A.

The conversion circuit 160A is a so-called Marchand balun. The conversion circuit 160A includes lines 161 and 162 each with a length of λ/ 4 and a line 163 with a length of λ/2.

A first end of the line 161 is connected to the output terminal of the TLT 150A with the capacitor C4 interposed therebetween, and a second end of the line 161 is connected to a ground potential GND. Similarly, a first end of the line 162 is connected to the output terminal of the TLT 150B with the capacitor C5 interposed therebetween, and a second end of the line 162 is connected to a ground potential GND.

The line 163 includes partial lines 1631 and 1632, and first ends of the partial lines 1631 and 1632 are connected. A second end of the partial line 1631 is connected to the antenna ANT with the output terminal T2 interposed therebetween. A second end of the partial line 1632 is an open end. The partial line 1631 is coupled to the line 161, and the partial line 1632 is coupled to the line 162.

The individual lines are arranged in such a manner that directions of currents flowing in the line 161 and the line 162 are opposite to the direction of a current flowing in the line 163. Accordingly, high frequency signals from the TLTs 150A and 150B with a phase difference of 180 degrees are added together and output from the line 163.

In the case where a Marchand balun is used as a conversion circuit for conversion from a balanced line into an unbalanced line, although an area in which lines are formed on a substrate is slightly increased, transmission loss can be reduced compared to the case where an MCT is used as in the power amplifier circuit 100. Thus, the circuit efficiency in the power amplifier circuit can further be improved.

### Fourth Embodiment

In a fourth embodiment, other configurations regarding how power is supplied to individual amplifiers in the power amplifier stage 140 will be described.

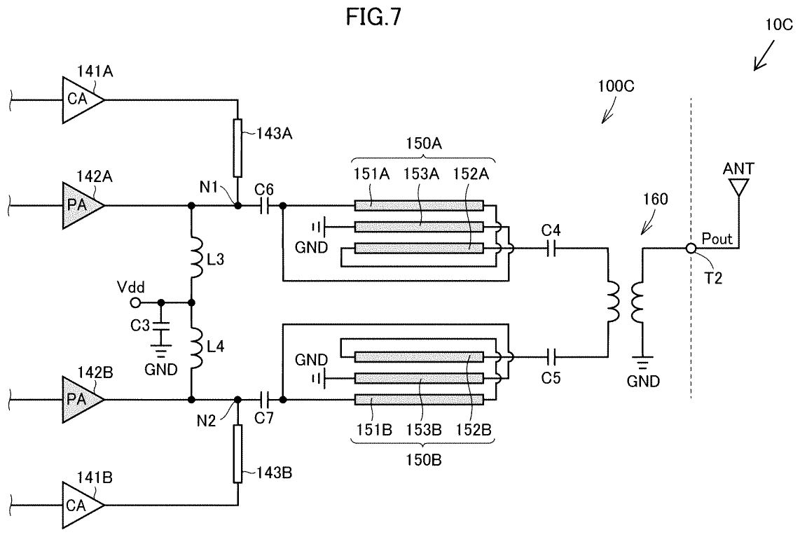

FIG. 7 is a partial circuit diagram of a transmission circuit 10C according to the fourth embodiment. In a power amplifier circuit 100C of the transmission circuit 10C, a power supply voltage Vdd for the carrier amplifiers 141A and 141B and the peak amplifiers 142A and 142B is supplied without going through the TLT 150A or 150B.

More specifically, first ends of the third line 153A of the TLT 150A and the third line 153B of the TLT 150B are connected to a ground potential GND not to the power supply voltage Vdd. Inductors L3 and L4 that are connected in series are connected between the output terminal of the peak amplifier 142A and the output terminal of the peak amplifier 142B, and the power supply voltage Vdd is supplied to a connection node between the inductor L3 and the inductor L4.

In this case, in order to prevent short-circuiting, the first line 151A and the third line 153A of the TLT 150A are connected to the connection node N1 with a capacitor C6 for DC cutting interposed therebetween. Similarly, the first line 151B and the third line 153B of the TLT 150B are connected to the connection node N2 with a capacitor C7 for DC cutting interposed therebetween.

The power supply voltage Vdd is supplied to the carrier amplifier 141A and the peak amplifier 142A through the inductor L3. Furthermore, the power supply voltage Vdd is supplied to the carrier amplifier 141B and the peak amplifier 142B through the inductor L4. The inductors L3 and L4 enable the output impedance of the peak amplifiers 142A and 142B to be in an open state. Furthermore, voltage variations of the power supply voltage Vdd are suppressed by the capacitor C3 as a bypass capacitor.

In the case where power supply to each amplifier in the power amplifier stage 140 is performed through a TLT as in the power amplifier circuit 100 according to the first embodiment, a line length in the TLT is not necessarily set to ¼ wavelength. Therefore, there may be a case where a power line does not appear open when seen from an output end of the amplifier. Thus, as in the power amplifier circuit 100C according to the fourth embodiment, by performing power supply to amplifiers through the individual inductors L3 and L4, it is possible to clearly show that a power line appears open.

### Fifth Embodiment

In a fifth embodiment, a high frequency termination circuit for eliminating a harmonic wave of a high frequency signal will be described.

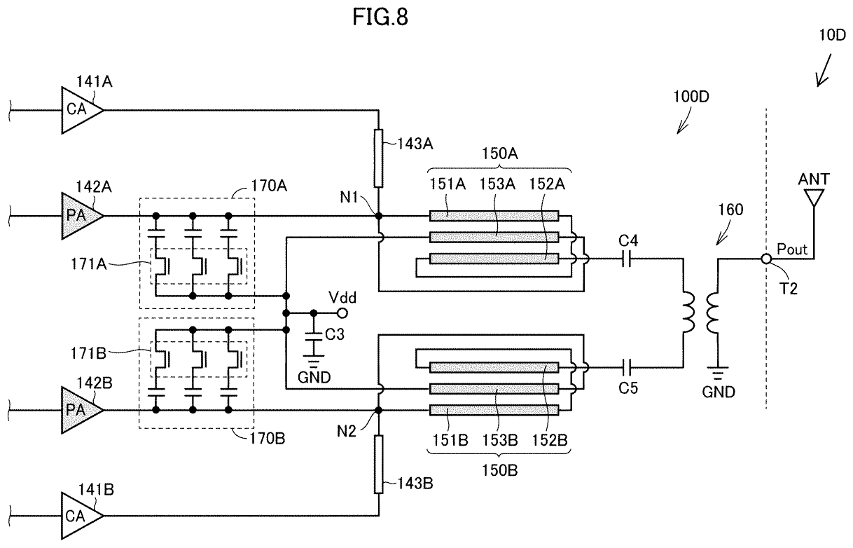

FIG. 8 is a partial circuit diagram of a transmission circuit 10D according to the fifth embodiment. In a power amplifier circuit 100D in the transmission circuit 10D, capacitor circuits 170A and 170B are added between the third line 153A of the TLT 150A and the output terminal of the peak amplifier 142A and between the third line 153B of the TLT 150B and the output terminal of the peak amplifier 142B, respectively, in addition to the configuration of the power amplifier circuit 100 illustrated in FIG. 1.

Each of the capacitor circuits 170A and 170B includes at least one capacitor and a switching circuit for switching the capacitor. In the example of the power amplifier circuit 100D, each of the capacitor circuits 170A and 170B includes three capacitors and three switching elements provided in association with the capacitors.

In the capacitor circuit 170A, pairs each including a capacitor and a switching element that are connected in series are connected in parallel between the third line 153A of the TLT 150A and the output terminal of the peak amplifier 142A. In the capacitor circuit 170B, pairs each including a capacitor and a switching element that are connected in series are connected in parallel between the third line 153B of the TLT 150B and the output terminal of the peak amplifier 142B.

Switching elements included in the capacitor circuit 170A are collectively referred to as a switching circuit 171A. Switching elements included in the capacitor circuit 170B are collectively referred to as a switching circuit 171B.

In each of the capacitor circuits, by causing any one of the switching elements to be electrically connected, a capacitor connected to the corresponding switching element and a third line of a corresponding TLT form an LC parallel resonance circuit.

Typical LC parallel resonance circuits have characteristics in which capacitance increases and admittance increases as the frequency increases in a frequency region higher than a resonant frequency. Thus, by properly setting the resonant frequency of the corresponding LC parallel resonance circuit, the output impedance of a peak amplifier can be short-circuited in a second-order harmonic band or a third-order harmonic band of a high frequency signal transmitted, and attenuation in the corresponding harmonic wave band can be ensured. Accordingly, leakage of a high frequency signal in a target frequency band to a power line can be prevented to improve the circuit efficiency, and a harmonic wave of a high frequency signal can be suppressed.

Furthermore, as described above in the fourth embodiment, in the case where power supply is performed through a TLT, there may be a case where the line length of the third line of the TLT is not set to ¼ wavelength. In that case, a situation may occur in which a power line does not appear open when seen from an output end of an amplifier. Even in such a case, by forming an LC parallel resonance circuit including a capacitor included in a capacitor circuit and a third line of a TLT, a power line can be adjusted to be in the open state with respect to a fundamental wave of a high frequency signal transmitted.

Each capacitor circuit does not necessarily include a plurality of capacitors. However, for example, in the case of a transmission circuit of a dual band type that transmits signals in a plurality of frequency bands in such a manner that switching is performed between the plurality of frequency bands, by providing capacitors corresponding to the individual frequency bands to be used, characteristics can be improved in the plurality of frequency bands.

The “capacitor circuit 170A” and the “capacitor circuit 170B” in the fifth embodiment correspond to a “first capacitor circuit” and a “second capacitor circuit”, respectively, in the present disclosure.

### Sixth Embodiment

In a sixth embodiment, a high frequency termination circuit for eliminating a second-order harmonic wave of a high frequency signal will be described.

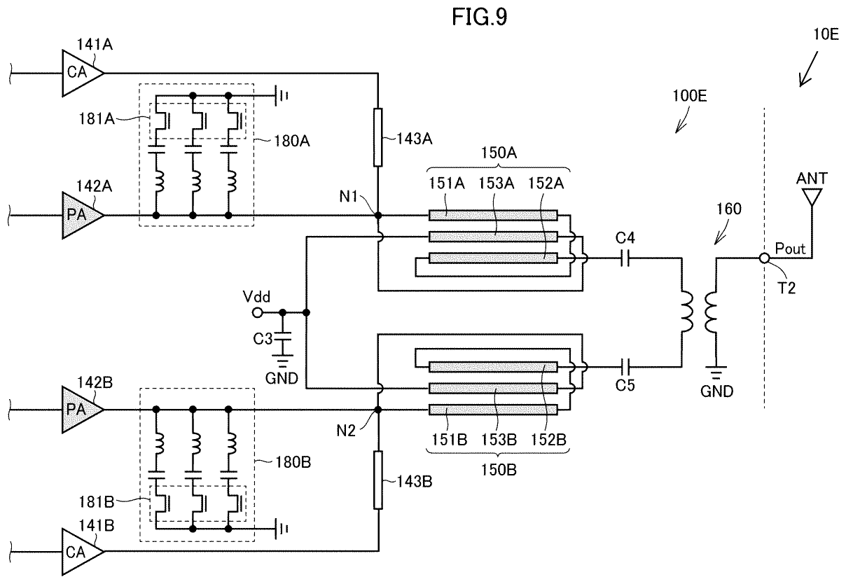

FIG. 9 is a partial circuit diagram of a transmission circuit 10E according to the sixth embodiment. In a power amplifier circuit 100E of the transmission circuit 10E, resonator circuits 180A and 180B each including at least one LC series resonance circuit are added between the output terminals of the peak amplifiers 142A and 142B, respectively, and a ground potential GND, in addition to the configuration of the power amplifier circuit 100 illustrated in FIG. 1.

The resonator circuits 180A and 180B include, in addition to the at least one LC series resonance circuit, switching circuits 181A and 181B, respectively, for switching the resonators. Each of the switching circuits includes a switching element connected in series to the at least one LC series resonance circuit. In each of the resonator circuits 180A and 180B, by causing the at least one switching element to be electrically connected, a corresponding LC series resonance circuit functions as a band stop filter. That is, a component corresponding to the resonant frequency of the corresponding LC series resonance circuit in a high frequency signal can be eliminated.

Thus, by setting the resonant frequency of the LC series resonance circuit to a second-order harmonic frequency of a high frequency signal to be transmitted, a component of a second-order harmonic wave of the high frequency signal can be eliminated.

The “resonator circuit 180A” and the “resonator circuit 180B” in the sixth embodiment correspond to a “first resonator circuit” and a “second resonator circuit”, respectively, in the present disclosure.

### Seventh Embodiment

In a seventh embodiment, a different arrangement configuration of the radiating element 220 at the dielectric substrate 230 will be described.

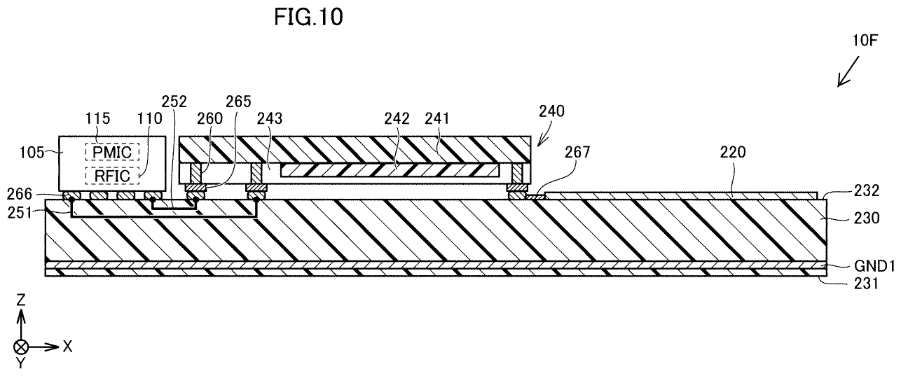

FIG. 10 is a perspective side view of a transmission circuit 10F according to the seventh embodiment. The transmission circuit 10F is different from the transmission circuit 10 according to the first embodiment described above with reference to FIG. 2 in that the radiating element 220 is arranged on the main face 232 of the dielectric substrate 230, that is, a main face on which the amplifier module 240 and the SiP module 105 are mounted.

The dimension in the X-axis direction of the dielectric substrate 230 in the transmission circuit 10F is larger than that in the transmission circuit 10. On the main face 232, the radiating element 220 is arranged in the X-axis position direction relative to the amplifier module 240. A high frequency signal from the amplifier module 240 is transmitted, through a power supply wire 267 arranged on the main face 232, to the radiating element 220. The power supply wire 267 may be connected, through an inner layer of the dielectric substrate 230, to the radiating element 220.

In the example of FIG. 10, the radiating element 220 is a patch antenna of a flat plate shape. Therefore, the ground electrode GND1 at the dielectric substrate 230 extends to a position opposite to the radiating element 220. Furthermore, in the transmission circuit 10F, in order to expand the band width of a radio wave radiated from the radiating element 220, the ground electrode GND1 is arranged at a layer close to the main face 231 of the dielectric substrate 230.

With the configuration described above, since the distance between the amplifier module 240 and the radiating element 220 can be reduced, impedance matching can be easily achieved, and loss caused by a power supply wire can also be reduced. Therefore, the advantage of easily obtaining desired antenna characteristics can be attained.

In contrast, in the case where the radiating element 220 is arranged on the main face 231 that is opposite to the face on which the amplifier module 240 is mounted, as in the transmission circuit 10 according to the first embodiment, the dimension in the X-axis direction of the dielectric substrate 230 can be reduced. Therefore, miniaturization of the entire apparatus can be achieved.

A selection as to which one of the configuration of the transmission circuit 10 and the configuration of the transmission circuit 10F is to be adopted is made appropriately in accordance with constraints of dimensions of the apparatus and/or required antenna characteristics.

### Eighth Embodiment

In an eighth embodiment, a different arrangement configuration of the SiP module 105 at the dielectric substrate 230 will be described.

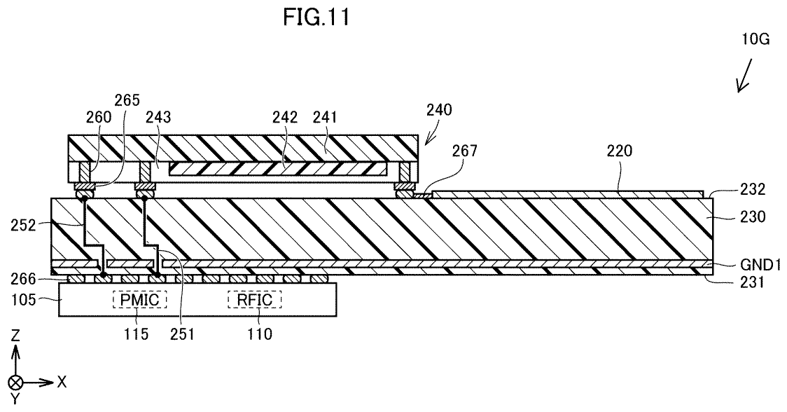

FIG. 11 is a perspective side view of a transmission circuit 10G according to the eighth embodiment. The transmission circuit 10G has a configuration in which the SiP module 105 in the transmission circuit 10F according to the seventh embodiment is arranged on the main face 231.

With the arrangement described above, compared to the transmission circuit 10F according to the seventh embodiment, although the dimension in the Z-axis direction of the entire apparatus slightly increases, the dimension in the X-axis direction can be reduced. Thus, the area in which the transmission circuit is mounted can be reduced.

### Ninth Embodiment

In a ninth embodiment, a configuration in which a radiating element is arranged in an amplifier module will be described.

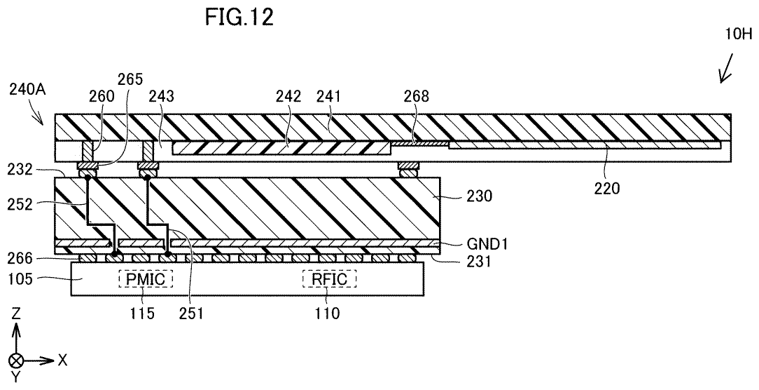

FIG. 12 is a perspective side view of a transmission circuit 10H according to the ninth embodiment. In the transmission circuit 10H, the SiP module 105 is arranged on the main face 231 of the dielectric substrate 230 as in the transmission circuit 10G according to the eighth embodiment, and an amplifier module 240A, instead of the amplifier module 240, is arranged on the main face 232.

In the amplifier module 240A, in addition to the semiconductor substrate 242 made of a group III-V compound, the radiating element 220 is also arranged, at a position in the X-axis positive direction relative to the semiconductor substrate 242, on the semiconductor substrate 241 made of a Si-based material. A high frequency signal from the semiconductor substrate 242 is supplied, through a power supply wire 268 arranged at the semiconductor substrate 241, to the radiating element 220. The semiconductor substrate 242, the radiating element 220, and the power supply wire 268 are molded with the resin 243 at the semiconductor substrate 241.

To achieve the configuration described above, the dimension in the X-axis direction of the semiconductor substrate 241 is expanded. Meanwhile, in order not to prevent radiation of radio waves from the radiating element 220, the dimension in the X-axis direction of the dielectric substrate 230 is shortened, and the amplifier module 240A protrudes relative to an end portion in the X-axis positive direction of the dielectric substrate 230. In other words, the radiating element 220 is arranged so as not to overlap with the dielectric substrate 230 when seen in plan view from the normal direction of the dielectric substrate 230.

In the case of the arrangement of the transmission circuit 10H, since no ground electrode is provided at the amplifier module 240A, the radiating element 220 is not a patch antenna but a linear antenna such as a monopole antenna or a dipole antenna.

In the case where an amplifier and an antenna are connected by soldering, an increase of loss and/or variations in characteristics may occur depending on the state of soldered connection. However, as in the eighth embodiment, by directly connecting an amplifier to an antenna on a semiconductor substrate, production variations in the process of assembling can be reduced. Thus, stable characteristics of products can be achieved.

### Modification

The transmission circuit 10H according to the ninth embodiment with a configuration in which the amplifier module 240A mounted at the dielectric substrate 230 protrudes relative to the dielectric substrate 230 only in the X-axis positive direction has been described above. In a modification, a configuration in which a transmission circuit protrudes relative to the dielectric substrate 230 in two directions and a radiating element is arranged in each of the protruding parts will be described.

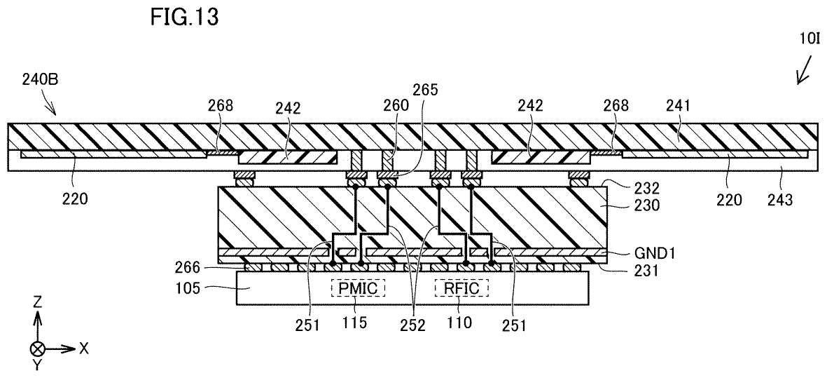

FIG. 13 is a perspective side view of a transmission circuit 10I according to a modification. In the transmission circuit 10I, the amplifier module 240A in the transmission circuit 10H according to the ninth embodiment is replaced by an amplifier module 240B. In FIG. 13, description of elements overlapping with those in FIG. 12 is not provided.

The dimension in the X-axis direction of the amplifier module 240B is larger than that of the amplifier module 240A in the transmission circuit 10H, and the amplifier module 240B protrudes relative to the dielectric substrate 230 in both the positive and negative directions of the X-axis. In each of the protruding parts on the semiconductor substrate 241, the radiating element 220 is arranged. Furthermore, the semiconductor substrate 242 at which the peak amplifier 142 is formed is arranged for each of the radiating elements 220.

In FIG. 13, the separate semiconductor substrates 242 are provided for the individual radiating elements 220. However, a single semiconductor substrate 242 at which the peak amplifier 142 corresponding to the two radiating elements 220 is formed may be arranged. Since a material for a group III-V compound is expensive, if the area of the semiconductor substrate 242 is large, it is desirable that separate substrates be arranged from the viewpoint of cost. Furthermore, also in the case where the length of a power supply wire 268 from a semiconductor substrate 242 to a radiating element 220 is increased by using a single semiconductor substrate 242, it is desirable, from the viewpoint of loss reduction, that the distance between the radiating element 220 and the semiconductor substrate 242 be shortened by arranging separate substrates.

Also, in the transmission circuit 10G illustrated in FIG. 11, the amplifier module 240 may be arranged to protrude relative to the dielectric substrate 230 on both sides, as in the modification.

### Aspects

It should be understood by those skilled in the art that a plurality of illustrative embodiments described above are specific examples of aspects described below.
(Aspect 1) A power amplifier circuit according to an aspect includes an input terminal and an output terminal; a splitter; a first amplifier and a second amplifier; a first phase adjuster; a first substrate; and a second substrate mounted on the first substrate. The splitter is connected to the input terminal and distributes an input signal from the input terminal into a first path and a second path. The first amplifier is connected to the first path for the splitter. The second amplifier is connected to the second path for the splitter. The first phase adjuster is connected between an output of the first amplifier and an output of the second amplifier. The first amplifier is formed at the first substrate. The second amplifier is formed at the second substrate. The first amplifier and the second amplifier configure a Doherty amplifier. The output terminal is electrically connected to a connection node between the second amplifier and the first phase adjuster. The first amplifier is a carrier amplifier and the second amplifier is a peak amplifier. The first substrate is a semiconductor substrate including a material containing a Si-based base material as a main component. The second substrate is a semiconductor substrate including a material containing, as a main component, a compound of an element from group III and an element from group V.
(Aspect 2) The power amplifier circuit according to aspect 1 further includes a first preamplifier and a second preamplifier; a third amplifier and a fourth amplifier; a second phase adjuster; and a conversion circuit. The first preamplifier is connected to the first path, amplifies the input signal, and outputs two signals with a phase difference to two balanced lines. The second preamplifier is connected to the second path, amplifies the input signal, and outputs two signals with a phase difference to two balanced lines. The second phase adjuster is connected between an output of the third amplifier and an output of the fourth amplifier. The conversion circuit converts a balanced line into an unbalanced line. The first amplifier is connected to a first one of the balanced lines of the first preamplifier, and the third amplifier is connected to a second one of the balanced lines of the first preamplifier. The second amplifier is connected to a first one of the balanced lines of the second preamplifier, and the fourth amplifier is connected to a second one of the balanced lines of the second preamplifier. A combined signal from a connection node between the first amplifier and the first phase adjuster is supplied to a first balanced line of the conversion circuit. A combined signal from a connection node between the third amplifier and the second phase adjuster is supplied to a second balanced line of the conversion circuit. The unbalanced line of the conversion circuit is connected to the output terminal.
(Aspect 3) In the power amplifier circuit according to aspect 2, the conversion circuit is a magnetic coupled transformer.
(Aspect 4) In the power amplifier circuit according to aspect 2, the conversion circuit is a Marchand balun.
(Aspect 5) The power amplifier circuit according to any one of aspects 2 to 4 further includes a first transmission line transformer and a second transmission line transformer. The first transmission line transformer is connected between the first balanced line of the conversion circuit and the output of the second amplifier. The second transmission line transformer is connected between the second balanced line of the conversion circuit and the output of the fourth amplifier.
(Aspect 6) In the power amplifier circuit according to aspect 5, the first transmission line transformer includes a first line, a second line, and a third line. The first line and the second line are connected in series between the first balanced line and the output of the second amplifier. The third line is coupled to the first line and the second line. The second transmission line transformer includes a fourth line, a fifth line, and a sixth line. The fourth line and the fifth line are connected in series between the second balanced line and the output of the fourth amplifier. The sixth line is coupled to the fourth line and the fifth line.
(Aspect 7) In the power amplifier circuit according to aspect 6, a first end of the third line is connected to the output of the second amplifier. A first end of the sixth line is connected to the output of the fourth amplifier. A power supply voltage is supplied to a second end of the third line and a second end of the sixth line.
(Aspect 8) The power amplifier circuit according to aspect 7 further includes a first capacitor circuit and a second capacitor circuit. The first capacitor circuit is connected between the second end of the third line and the output of the second amplifier. The second capacitor circuit is connected between the second end of the sixth line and the output of the fourth amplifier. The first capacitor circuit includes a plurality of capacitors connected in parallel between the second end of the third line and the output of the second amplifier. The second capacitor circuit includes a plurality of capacitors connected in parallel between the second end of the sixth line and the output of the fourth amplifier. Each of the first capacitor circuit and the second capacitor circuit further includes a switching circuit for switching between the plurality of capacitors.
(Aspect 9) The power amplifier circuit according to aspect 7 further includes a first resonator circuit and a second resonator circuit. The first resonator circuit is connected between the second end of the third line and a ground potential. The second resonator circuit is connected between the second end of the sixth line and the ground potential. The first resonator circuit includes a plurality of LC series resonators connected in parallel between the second end of the third line and the ground potential. The second resonator circuit includes a plurality of LC series resonators connected in parallel between the second end of the sixth line and the ground potential. Each of the first resonator circuit and the second resonator circuit further includes a switching circuit for switching between the plurality of LC series resonators.
(Aspect 10) In the power amplifier circuit according to aspect 6, a first end of the third line is connected to the output of the second amplifier. A first end of the sixth line is connected to the output of the fourth amplifier. A second end of the third line and a second end of the sixth line are connected to a ground potential. A power supply voltage is supplied, through inductors, to the output of the second amplifier and the output of the fourth amplifier.
(Aspect 11) In the power amplifier circuit according to any one of aspects 1 to 10, the first amplifier is a Class A amplifier or a Class AB amplifier. The second amplifier is a Class C amplifier.
(Aspect 12) A transmission circuit according to an aspect includes a dielectric substrate; the power amplifier circuit according to any one of aspects 1 to 11; a radiating element; and a power supply circuit. The dielectric substrate includes a first face and a second face that are opposite to each other. The power amplifier circuit is arranged on the first face of the dielectric substrate. The power supply circuit supplies, through the power amplifier circuit, a high frequency signal to the radiating element.
(Aspect 13) In the transmission circuit according to aspect 12, the radiating element is arranged on the first face of the dielectric substrate.
(Aspect 14) In the transmission circuit according to aspect 12, the radiating element is arranged on the second face of the dielectric substrate.
(Aspect 15) In the transmission circuit according to aspect 12, the radiating element is arranged at the first substrate of the power amplifier circuit.
(Aspect 16) In the transmission circuit according to any one of aspects 12 to 15, the power supply circuit is arranged on the first face of the dielectric substrate.
(Aspect 17) In the transmission circuit according to any one of aspects 12 to 15, the power supply circuit is arranged on the second face of the dielectric substrate.
(Aspect 18) In the transmission circuit according to any one of aspects 12 to 15, the power supply circuit is formed at the first substrate.

The embodiments disclosed herein are to be considered in all respects to be illustrative and not restrictive. The scope of the present disclosure is defined by the claims, rather than the embodiments described above, and is intended to include all modifications within the meaning and scope equivalent to the scope of the claims.

10, 10A to 10I transmission circuit, 100, 100B to 100E power amplifier circuit, 105 SiP module, 110 RFIC, 115 PMIC, 120 splitter, 130, 135 preamplifier, 131, 136 driving amplifier, 140 power amplifier stage, 141, 141A, 141B carrier amplifier, 142, 142A, 142B peak amplifier, 143, 143A, 143B phase adjuster, 150A, 150B TLT, 160, 160A conversion circuit, 151A to 153A, 151B to 153B, 161 to 163, 1631, 1632 line, 170A, 170B capacitor circuit, 171A, 171B, 181A, 181B switching circuit, 180A, 180B resonator circuit, 200 BBIC, 220 radiating element, 230 dielectric substrate, 231, 232 main face, 240, 240A, 240B amplifier module, 241, 242 semiconductor substrate, 243 resin, 251 to 253, 267, 268 power supply wire, 260 columnar electrode, 265 connecting electrode, 266 solder bump, ANT antenna, C1 to C7 capacitor, GND ground potential, GND1 ground electrode, L1 to L4 inductor, N1, N2 connection node, T1 input terminal, T2 output terminal, T3 power supply terminal, TR1, TR2 conversion transformer, TR3 magnetic coupled transformer, Vdd power supply voltage.

1. A power amplifier circuit comprising:
an input terminal and an output terminal;
a splitter that is connected to the input terminal and that is configured to distribute an input signal from the input terminal into a first path and a second path;
a first amplifier that is connected to the first path;
a second amplifier that is connected to the second path;
a first phase adjuster that is connected between an output of the first amplifier and an output of the second amplifier;
a first substrate at which the first amplifier is arranged; and
a second substrate at which the second amplifier is arranged, the second substrate being mounted on the first substrate,
wherein the first amplifier and the second amplifier constitute a Doherty amplifier,
wherein the first amplifier is a carrier amplifier and the second amplifier is a peak amplifier,
wherein the output terminal is electrically connected to a connection node between the second amplifier and the first phase adjuster,
wherein the first substrate is a semiconductor substrate having a material containing, as a main component, a Si-based base material, and
wherein the second substrate is a semiconductor substrate having a material containing, as a main component, a compound of an element from group III and an element from group V.

2. The power amplifier circuit according to claim 1, further comprising:
a first preamplifier that is connected to the first path, and that is configured to amplify the input signal and to output two signals with a phase difference to two balanced lines;
a second preamplifier that is connected to the second path, and that is configured to amplify the input signal and to output two signals with a phase difference to two balanced lines;
a third amplifier and a fourth amplifier;
a second phase adjuster that is connected between an output of the third amplifier and an output of the fourth amplifier; and
a conversion circuit configured to convert a balanced line into an unbalanced line,
wherein the first amplifier is connected to a first one of the balanced lines of the first preamplifier, and the third amplifier is connected to a second one of the balanced lines of the first preamplifier,
wherein the second amplifier is connected to a first one of the balanced lines of the second preamplifier, and the fourth amplifier is connected to a second one of the balanced lines of the second preamplifier,
wherein a combined signal from a connection node between the first amplifier and the first phase adjuster is supplied to a first balanced line of the conversion circuit,
wherein a combined signal from a connection node between the third amplifier and the second phase adjuster is supplied to a second balanced line of the conversion circuit, and
wherein the unbalanced line of the conversion circuit is connected to the output terminal.

3. The power amplifier circuit according to claim 2, wherein the conversion circuit is a magnetic coupled transformer.

4. The power amplifier circuit according to claim 2, wherein the conversion circuit is a Marchand balun.

5. The power amplifier circuit according to claim 2, further comprising:
a first transmission line transformer that is connected between the first balanced line of the conversion circuit and the output of the second amplifier; and
a second transmission line transformer that is connected between the second balanced line of the conversion circuit and the output of the fourth amplifier.

6. The power amplifier circuit according to claim 5,
wherein the first transmission line transformer comprises:
a first line and a second line that are connected in series between the first balanced line and the output of the second amplifier; and
a third line that is coupled to the first line and the second line, and
wherein the second transmission line transformer comprises:
a fourth line and a fifth line that are connected in series between the second balanced line and the output of the fourth amplifier; and
a sixth line that is coupled to the fourth line and the fifth line.

7. The power amplifier circuit according to claim 6,
wherein a first end of the third line is connected to the output of the second amplifier,
wherein a first end of the sixth line is connected to the output of the fourth amplifier, and
wherein a power supply voltage is supplied to a second end of the third line and a second end of the sixth line.

8. The power amplifier circuit according to claim 7, further comprising:
a first capacitor circuit that is connected between the second end of the third line and the output of the second amplifier; and
a second capacitor circuit that is connected between the second end of the sixth line and the output of the fourth amplifier,
wherein the first capacitor circuit comprises a plurality of capacitors connected in parallel between the second end of the third line and the output of the second amplifier,
wherein the second capacitor circuit comprises a plurality of capacitors connected in parallel between the second end of the sixth line and the output of the fourth amplifier, and
wherein each of the first capacitor circuit and the second capacitor circuit further comprises a switching circuit configured to switch between the plurality of capacitors.

9. The power amplifier circuit according to claim 7, further comprising:
a first resonator circuit that is connected between the second end of the third line and a ground potential; and
a second resonator circuit that is connected between the second end of the sixth line and the ground potential,
wherein the first resonator circuit comprises a plurality of LC series resonators connected in parallel between the second end of the third line and the ground potential,
wherein the second resonator circuit comprises a plurality of LC series resonators connected in parallel between the second end of the sixth line and the ground potential, and
wherein each of the first resonator circuit and the second resonator circuit further comprises a switching circuit configured to switch between the plurality of LC series resonators.

10. The power amplifier circuit according to claim 6,
wherein a first end of the third line is connected to the output of the second amplifier,
wherein a first end of the sixth line is connected to the output of the fourth amplifier,
wherein a second end of the third line and a second end of the sixth line are connected to a ground potential, and
wherein a power supply voltage is supplied, through inductors, to the output of the second amplifier and the output of the fourth amplifier.

11. The power amplifier circuit according to claim 1,
wherein the first amplifier is a Class A amplifier or a Class AB amplifier, and
wherein the second amplifier is a Class C amplifier.

12. A transmission circuit comprising:
a dielectric substrate having a first face and a second face that are opposite to each other;
the power amplifier circuit according to claim 1 that is arranged on the first face of the dielectric substrate;
a radiating element; and
a power supply circuit that is configured to supply, through the power amplifier circuit, a high frequency signal to the radiating element.

13. The transmission circuit according to claim 12, wherein the radiating element is arranged on the first face of the dielectric substrate.

14. The transmission circuit according to claim 12, wherein the radiating element is arranged on the second face of the dielectric substrate.

15. The transmission circuit according to claim 12, wherein the radiating element is arranged at the first substrate of the power amplifier circuit.

16. The transmission circuit according to claim 12, wherein the power supply circuit is arranged on the first face of the dielectric substrate.

17. The transmission circuit according to claim 12, wherein the power supply circuit is arranged on the second face of the dielectric substrate.

18. The transmission circuit according to claim 12, wherein the power supply circuit is arranged at the first substrate.
